(19) United States
(12) Patent Application Publication
(10) Pub. No.: US 2022/0310702 A1
(43) Pub. Date: Sep. 29, 2022

(54) PIXEL ARRANGEMENT EVAPORATION METHOD AND PIXEL ARRANGEMENT DISPLAY DEVICE CAPABLE OF IMPROVING COLOR GAMUT AND PIXELS PER INCH (PPI)

(71) Applicant: WUHAN CHINA STAR OPTOELECTRONICS SEMICONDUCTOR DISPLAY TECHNOLOGY c\CO., LTD., Wuhan (CN)

(72) Inventor: Ruiting HE, Wuhan (CN)

(73) Assignee: WUHAN CHINA STAR OPTOELECTRONICS SEMICONDUCTOR DISPLAY TECHNOLOGY c\CO., LTD., Wuhan (CN)

(21) Appl. No.: 16/757,780

(22) PCT Filed: Apr. 13, 2020
(86) PCT No.: PCT/CN2020/084512

§ 371 Date: Apr. 21, 2020

(30) Foreign Application Priority Data
Mar. 2, 2020 (CN) 202010133953.0

(51) Int. Cl. H01L 27/32; H01L 51/00

(52) U.S. Cl. CPC H01L 27/3216; H01L 51/0011

(57) ABSTRACT

A pixel arrangement evaporation method and a pixel arrangement display device capable of improving color gamut and pixels per inch (PPI) are provided. On an evaporation substrate, an R pixel, a G pixel, and a B pixel that are triangular in shape, independently controllable, and light-emitting are sequentially arranged on the evaporation substrate. Adjacent-closely pixels with same appearance and color on an evaporation substrate are used as independent units. Number of pixels in three single-color, independent units arranged in a row can be the same. Number of sub-pixels of each of the independent units is 3N+1 or 3N+2, where N is a positive integer. A same unit is vapor-deposited into a film by using an evaporation method of a same fine metal mask (FMM) opening.

### FIELD OF INVENTION

The present application relates to organic light-emitting diode (OLED) device manufacturing, and in particular, to a pixel arrangement evaporation method and a pixel arrangement display device capable of improving color gamut and pixels per inch (PPD.

### BACKGROUND OF INVENTION

In recent years, the use of flat-panel displays in various products and fields requires the flat-panel displays to be further increased in size, high in image quality, and low in power consumption. Under such conditions, an organic electroluminescence (EL) display device including an organic EL device utilizing EL of an organic material is an all-solid-state type which is excellent in low-voltage driving, high-speed response, and spontaneous optical rotation. Flat panel displays have received a lot of attention.

At present, most OLED devices are manufactured with a fine metal mask (FMM) for RGB pixel EL film evaporation. Each FMM opening corresponds to a pixel. The existing mass production technology FMM designs an opening for a pixel single-layer film evaporation, as shown in FIG. 1. With an increase of market demand for high resolution, a diameter of FMM pixel openings is getting smaller and smaller, which greatly increases difficulty in controlling the FMM manufacturing process and the OLED evaporation process. When the resolution reaches more than 300 ppi, this arrangement requires that the opening and the connecting bridge (the ribs connecting adjacent openings) of the fine metal mask (FMM) are very small, which makes the mask processing difficult. Further, the alignment accuracy of mask, the shadow of mask, and the deformation of MASK due to other factors will seriously affect the evaporation of organic light-emitting materials to form a finely colored pixel pattern. In response to this problem in the industry, although leading companies such as South Korea's Samsung are also actively studying new technologies represented by laser thermal transfer (Laser-Induced Thermal Imaging; LITI) in order to produce high-resolution OLED displays. However, these new technologies still have many shortcomings, and currently cannot be used for mass production or low yield during mass production. For example, the need to increase the number of manufacturing processes and additional manufacturing processes results in lower production efficiency; the need to increase equipment and raw materials, and even need to develop special raw materials, resulting in increased investment and costs. Even so, it is still difficult for these new technologies to produce ultra-high resolution displays above 450 ppi. At the same time, small FMM pixel openings will also increase the frequency of FMM cleaning in the continuous evaporation process, resulting in reduced production capacity, waste of evaporation materials, and loss of FMM due to increased cleaning times.

### SUMMARY OF INVENTION

In view of the shortcomings of the prior art, the application discloses a pixel arrangement display device and a pixel arrangement evaporation method capable of improving the color gamut and PPI. When producing OLED screens with a same resolution, widths of the openings and connection bridges in this application are larger and easier to process and less deformed. The increase in the distance between different pixels is beneficial to avoid color mixing and to improve product yield. The evaporation alignment Margin is larger, and the evaporation process is easy to carry out, which solves the increase in productivity caused by the reduction of FMM replacement frequency and reduces FMM cleaning loss.

This application is implemented through the following technical solutions:

A pixel arrangement evaporation method capable of improving color gamut and pixels per inch (PPI), comprising following steps of:

a step S1 of using adjacent-closely pixels with same appearance and color on an evaporation substrate as independent units;

a step S2 of setting number of sub-pixels of each of the independent units to 3N+1 or 3N+2, where N is a positive integer;

a step S3 of setting fine metal mask (FMM) openings on the evaporation substrate; and

a step S4 of evaporating all of pixel arrangement methods set in the step S2 and a same unit to form a film by using an evaporation method of a same FMM opening.

Further, in the step S4, an evaporation zone is included during evaporation, and the evaporation zone is provided with an evaporation unit, an evaporation source, and an evaporation mask.

Further, the evaporation source is provided with evaporation source openings, each of evaporation source openings emits evaporation particles, and a restriction unit is used to set restriction openings through which the evaporation particles emitted from the evaporation source openings respectively pass.

Further, the evaporation mask is provided with evaporation openings in the vapor deposition areas where the vapor deposition particles reach the restriction openings respectively.

Further, an evaporation beam direction adjustment plate having evaporation beam passage holes is disposed and formed between the evaporation source and the evaporation mask, wherein a direction of an evaporation beam is controlled by passing the evaporation particles discharged from the evaporation source through an evaporation beam passage hole formed in the evaporation beam direction adjustment plate.

Further, the evaporation source openings are arranged at a fixed pitch along an X-axis direction, and each of the evaporation source openings has a nozzle shape opening upward parallel to a Z axis and emits the evaporation particles as material of a light-emitting layer toward the evaporation mask.

Further, the evaporation mask is a plate having a main surface parallel to an XY plane, wherein a plurality of mask openings are formed at different positions, in the X-axis direction, along the X-axis direction, wherein an opening shape of the mask openings is a triangular shape parallel to the Y axis.

Further, shape of the FMM opening is a triangle or a polygon other than the triangle.

The present application provides: a pixel arrangement display device capable of improving color gamut and PPI, the pixel arrangement display device used to implement the pixel arrangement evaporation method capable of improving color gamut and PPI described above, the pixel arrangement display device comprising: a display device and an evaporation substrate, wherein the display device comprises a plurality of pixels, and each of the plurality of pixels includes a plurality of sub-pixels of different colors, wherein on the evaporation substrate, an R pixel, a G pixel, and a B pixel that are triangular in shape, independently controllable, and light-emitting are sequentially arranged on the evaporation substrate, wherein adjacent-closely pixels with same appearance and color on an evaporation substrate are used as independent units, wherein number of the pixels in three single-color independent units can be the same in the independent units arranged in a same row.

Preferably, the R pixel is a red color triangle, the G pixel is a green color triangle, and the B pixel is a blue color triangle, wherein the sub-pixels with the same pixel color in the independent unit are adjacent to each other symmetrically, and widths of the longitudinal edges are equal to widths of the adjacent edges of an area composed of adjacent sub-pixels with the same color.

The beneficial effects of this application are that:

When producing OLED screens with the same resolution in this application, the mask of R, G, and B pixels is easier to process and less deformed than the mask of the existing FMM technology because of the larger width of the opening and the connecting bridge. The increase in distance between different pixels is beneficial to avoid color mixing, which is beneficial to improve product yield, larger evaporation alignment margin, lower FMM replacement frequency leading to increased productivity, and reduced FMM cleaning loss.

In the case that the width of the mask opening of the present application is the same as that of the existing FMM technology, the FMM connection bridge is wider and is not easily deformed, which can produce an OLED display with a higher pixel density. OLED device pixel arrangement design and evaporation method can both improve device resolution, improve the operability of FMM production and evaporation process, improve productivity and yield, and can provide OLED devices with excellent reliability and display quality at a low cost and stability.

### DESCRIPTION OF DRAWINGS

In order to more clearly describe embodiments of the present application or technical solutions in a conventional technology, drawings required to be used for the embodiments or descriptions of the conventional technology are simply described hereinafter. Apparently, the drawings described below only illustrate some embodiments of the present application. Those skilled in the art can obtain other drawings based on these drawings disclosed herein without creative effort.

FIG. 1 is a schematic diagram of an evaporation principle of a single-layer film of FMM pixels in the existing mass production technology;

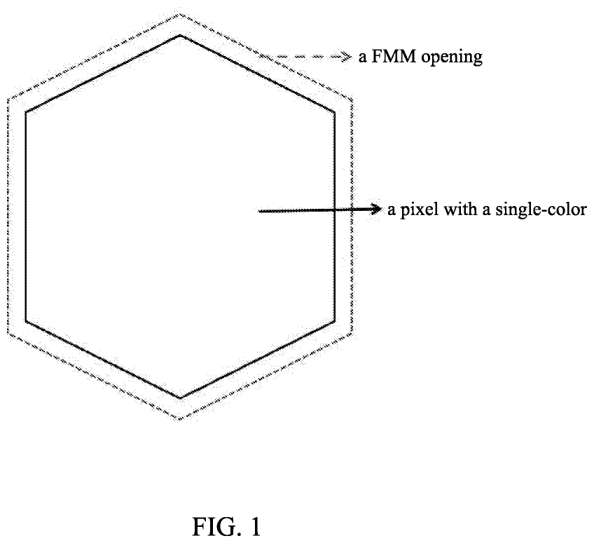

FIG. 2 is a schematic diagram of a pixel arrangement design and a evaporation method of a high color gamut and high PPI OLED device;

FIG. 3 is a schematic diagram of setting RGB pixels on an evaporation substrate according to an embodiment of the present application;

FIG. 4 is a schematic diagram of setting RGB pixels on an evaporation substrate according to another embodiment of the present application;

FIG. 5 is a schematic diagram, where number of sub-pixels of each of the three single-color independent units to 3N+1 or 3N+2, where N is a positive integer, wherein all of pixel arrangement methods and a same unit are evaporated to form a film by using an evaporation method of a same FMM opening;

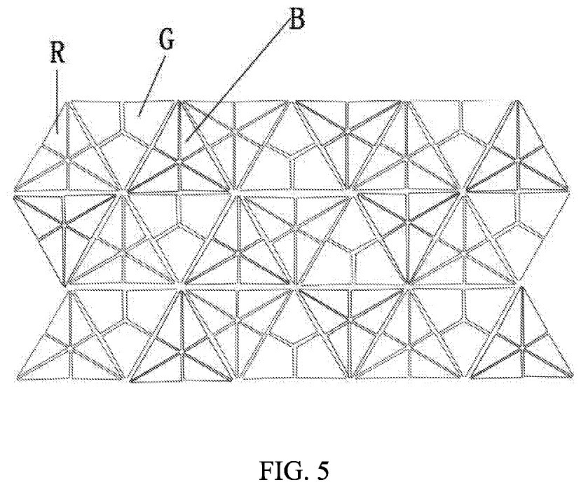

FIG. 6 is a schematic diagram of an opening method of FMM;

FIG. 7 is a schematic diagram of another opening method of FMM; and

FIG. 8 is a principle block diagram of a pixel arrangement evaporation method capable of improving color gamut and PPI according to an embodiment of the present application.

### DETAILED DESCRIPTION OF PREFERRED EMBODIMENTS

In order to make objects, technical solutions, and advantages of the embodiments of the present application clearer, technical solutions in the embodiments of the present application will be clearly and completely described below with reference to the accompanying drawings in the embodiments of the present application. Obviously, the described embodiments are part of embodiments of the present application, but not all the embodiments. Based on the embodiments in the present application, all other embodiments obtained by a person of ordinary skill in the art without creative efforts shall fall within the protection scope of the present application.

### Embodiment 1

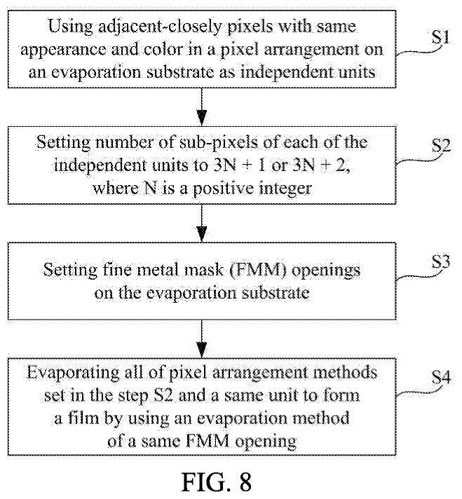

As shown in FIG. 8, this embodiment discloses a pixel arrangement evaporation method capable of improving color gamut and PPI, which includes the following steps:

a step S1 of using adjacent-closely pixels with same appearance and color on an evaporation substrate as independent units;

a step S2 of setting number of sub-pixels of each of the independent units to 3N+1 or 3N+2, where N is a positive integer;

a step S3 of setting fine metal mask (FMM) openings on the evaporation substrate; and

a step S4 of evaporating all of pixel arrangement methods set in the step S2 and a same unit to form a film by using an evaporation method of a same FMM opening.

In the step S4, an evaporation zone is included during evaporation, and the evaporation zone is provided with an evaporation unit, an evaporation source, and an evaporation mask. The evaporation source is provided with evaporation source openings, each of evaporation source openings emits evaporation particles, and a restriction unit is used to set restriction openings through which the evaporation particles emitted from the evaporation source openings respectively pass.

The evaporation mask is provided with evaporation openings in the vapor deposition areas where the vapor deposition particles reach the restriction openings respectively.

An evaporation beam direction adjustment plate having evaporation beam passage holes is disposed and formed between the evaporation source and the evaporation mask, wherein a direction of an evaporation beam is controlled by passing the evaporation particles discharged from the evaporation source through an evaporation beam passage hole formed in the evaporation beam direction adjustment plate.

The evaporation source openings are arranged at a fixed pitch along an X-axis direction, and each of the evaporation source openings has a nozzle shape opening upward parallel to a Z axis and emits the evaporation particles as material of a light-emitting layer toward the evaporation mask. The evaporation mask is a plate having a main surface parallel to an XY plane, wherein a plurality of mask openings are formed at different positions, in the X-axis direction, along the X-axis direction, wherein an opening shape of the mask openings is a triangular shape parallel to the Y axis. Shape of the FMM opening is a triangle or a polygon other than the triangle.

### Embodiment 2

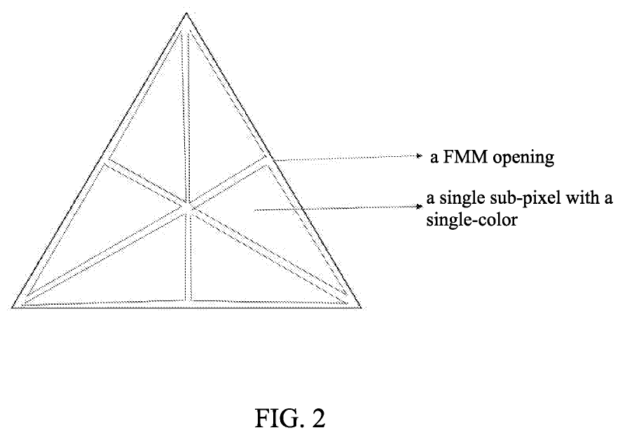

The present embodiment discloses a pixel arrangement design and an evaporation method for a high color gamut and high PPI OLED device, as shown in FIG. 2. An object is that, when producing OLED screens with the same resolution in this application, the mask of R, G, and B pixels is easier to process and less deformed than the mask of the existing FMM technology because of the larger width of the opening and the connecting bridge. The increase in distance between different pixels is beneficial to avoid color mixing, which is beneficial to improve product yield, larger evaporation alignment margin, easier evaporation process, lower FMM replacement frequency leading to increased productivity, and reduced FMM cleaning loss. Or in other words, in the case that the width of the mask opening is the same as that of the existing FMM technology, the FMM connection bridge is wider and is not easily deformed, which can produce an OLED display with a higher pixel density and a higher color gamut.

When producing OLED screens with the same resolution in an embodiment of this application, the mask of R, G, and B pixels is easier to process and less deformed than the mask of the existing FMM technology because of the larger width of the opening and the connecting bridge. The increase in distance between different pixels is beneficial to avoid color mixing, which is beneficial to improve product yield, larger evaporation alignment margin, lower FMM replacement frequency leading to increased productivity, and reduced FMM cleaning loss.

In the case that the width of the mask opening of an embodiment of the present application is the same as that of the existing FMM technology, the FMM connection bridge is wider and is not easily deformed, which can produce an OLED display with a higher pixel density. OLED device pixel arrangement design and evaporation method can both improve device resolution, improve the operability of FMM production and evaporation process, improve productivity and yield, and can provide OLED devices with excellent reliability and display quality at a low cost and stability.

### Embodiment 3

The present embodiment discloses a pixel arrangement display device and an evaporation method capable of improving color gamut and PPI. On an evaporation substrate, an R pixel, a G pixel, and a B pixel that are triangular in shape, independently controllable, and light-emitting are sequentially arranged on the evaporation substrate, wherein adjacent-closely pixels with same appearance and color on an evaporation substrate are used as independent units, wherein number of the pixels in three single-color independent units can be the same in the independent units arranged in a same row. Number of sub-pixels of each of the independent units to 3N+1 or 3N+2, where N is a positive integer, wherein all of pixel arrangement methods and a same unit are evaporated to form a film by using an evaporation method of a same FMM opening.

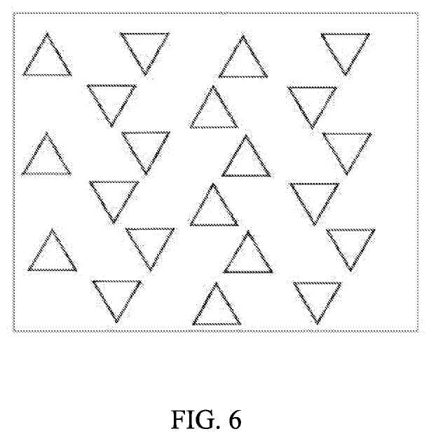

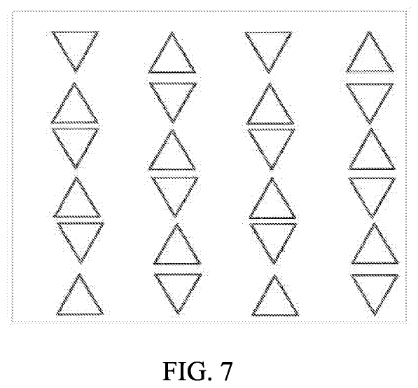

The FMM openings are shown in FIG. 6 and FIG. 7. Shape of the FMM openings is a triangle or a polygon other than a triangle.

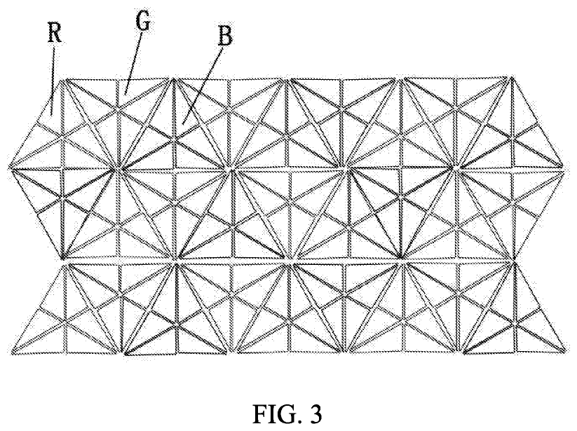

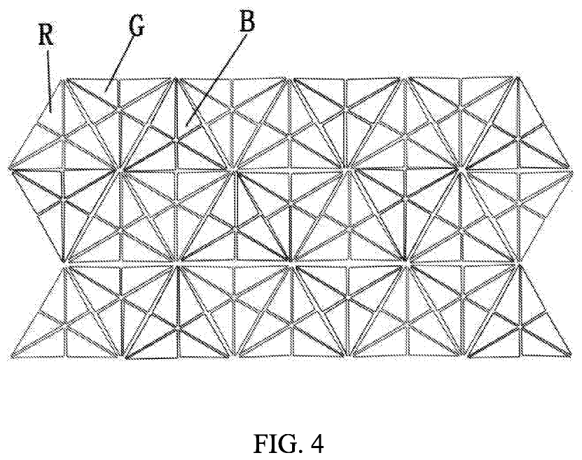

The arrangement design of R, G, and B pixels on the evaporation substrate is shown in FIG. 3 and FIG. 4, wherein the R pixel is a red color triangle, the G pixel is a green color triangle, and the B pixel is a blue color triangle.

An evaporation zone is included in the present embodiment, and the evaporation zone is provided with an evaporation unit, an evaporation source, and an evaporation mask. The evaporation source is provided with evaporation source openings, each of evaporation source openings emits evaporation particles, and a restriction unit is used to set restriction openings through which the evaporation particles emitted from the evaporation source openings respectively pass.

The evaporation mask is provided with evaporation openings in the vapor deposition areas where the vapor deposition particles reach the restriction openings respectively. An evaporation beam direction adjustment plate having evaporation beam passage holes is disposed and formed between the evaporation source and the evaporation mask, wherein a direction of an evaporation beam is controlled by passing the evaporation particles discharged from the evaporation source through an evaporation beam passage hole formed in the evaporation beam direction adjustment plate.

The evaporation source openings are arranged at a fixed pitch along an X-axis direction, and each of the evaporation source openings has a nozzle shape opening upward parallel to a Z axis and emits the evaporation particles as material of a light-emitting layer toward the evaporation mask. The evaporation mask is a plate having a main surface parallel to an XY plane, wherein a plurality of mask openings are formed at different positions, in the X-axis direction, along the X-axis direction, wherein an opening shape of the mask openings is a triangular shape parallel to the Y axis.

The sub-pixels with the same pixel color in the independent unit are adjacent to each other symmetrically, and widths of the longitudinal edges are equal to widths of the adjacent edges of an area composed of adjacent sub-pixels with the same color.

In the present embodiment, OLED device pixel arrangement design and evaporation method can both improve device resolution, improve the operability of FMM production and evaporation process, improve productivity and yield, and can provide OLED devices with excellent reliability and display quality at a low cost and stability.

### Embodiment 4

The present embodiment discloses a pixel arrangement display device and an evaporation method capable of improving color gamut and PPI. On an evaporation substrate, an R pixel, a G pixel, and a B pixel that are triangular in shape, independently controllable, and light-emitting are sequentially arranged on the evaporation substrate, wherein adjacent-closely pixels with same appearance and color on an evaporation substrate are used as independent units, wherein number of the pixels in three single-color independent units can be the same in the independent units arranged in a same row. Number of sub-pixels of each of the independent units to 3N+1 or 3N+2, where N is a positive integer, wherein all of pixel arrangement methods and a same unit are evaporated to form a film by using an evaporation method of a same FMM opening. An evaporation zone is included, and the evaporation zone is provided with an evaporation unit, an evaporation source, and an evaporation mask.

An evaporation beam direction adjustment plate having evaporation beam passage holes is disposed and formed between the evaporation source and the evaporation mask, wherein a directivity of an evaporation beam is improved by passing the evaporation particles discharged from the evaporation source through an evaporation beam passage hole formed in the evaporation beam direction adjustment plate. In order to sufficiently improve directivity, a diameter of the evaporation beam passage hole is preferably about 0.1 mm to 1 mm. However, when using such an evaporation beam direction adjustment plate in which an evaporation beam passage hole having a small diameter is formed, there is a same problem as when an aspect ratio of the mask opening is increased as described above. That is, the evaporation n beam passing hole has a small diameter, and the evaporation particles are likely to adhere to the inner peripheral surface of the vapor deposition beam passing hole and cause clogging.

In addition, it is technically difficult to form a plurality of small-diameter evaporation beam passage holes with high accuracy, and the cost becomes high. When the diameter of the evaporation beam passage hole is increased to improve the processability, in order to obtain a desired directivity of the evaporation beam, it is necessary to thicken the evaporation beam direction adjustment plate. As a result, the self-weight of the evaporation beam direction adjustment plate causes flexure and deformation, and the directivity and the width of the blurred portion are no longer fixed. The amount of vapor deposition particles that cannot pass through the evaporation beam passage holes is large, and the evaporation rate is reduced.

The use efficiency of the evaporation material is reduced. In the new evaporation method, the evaporation beam direction adjustment plate is used, but it is not necessary to improve the directivity of the evaporation beam. In a direction parallel to the moving direction of the substrate, an evaporation beam having poor directivity is captured. As a result, the utilization efficiency of the evaporation material is undesirably reduced.

In this embodiment, there is an advantage that a large-sized substrate can be split coating evaporated, and it is difficult to reduce the width of the blurred portion while preventing the use efficiency of the evaporation material from decreasing. In order to prevent the blurred part from reaching adjacent light emitting layer regions of different colors so that color mixing does not occur, it is necessary to reduce the pixel opening width or increase the pixel interval to increase the non-light emitting area. However, if the opening width of the pixel is reduced, the light emitting area is reduced and the brightness is reduced. If the current density is increased in order to obtain the required brightness, the life of the organic EL device is shortened, or the organic EL device is easily damaged, and the reliability is lowered. On the other hand, if the pixel pitch is increased, high-definition display cannot be achieved, and display quality is reduced.

Therefore, in the present embodiment, on an evaporation substrate, an R pixel, a G pixel, and a B pixel that are triangular in shape, independently controllable, and light-emitting are sequentially arranged on the evaporation substrate, wherein adjacent-closely pixels with same appearance and color on an evaporation substrate are used as independent units, wherein number of the pixels in three single-color independent units can be the same in the independent units arranged in a same row. Number of sub-pixels of each of the independent units to 3N+1 or 3N+2, where N is a positive integer, wherein all of pixel arrangement methods and a same unit are evaporated to form a film by using an evaporation method of a same FMM opening.

Six sub-pixels with the same R, G, and B are arranged together as a unit. This unit can be evaporated through a triangular FMM opening, but the sub-pixels emit light separately. A distance between the same sub-pixels in one unit of the above-mentioned backplane when making R, G, and B pixels can be reasonably reduced, and the distance between them and adjacent different units increases accordingly. When producing OLED screens with the same resolution, the mask of R, G, and B pixels is easier to process and less deformed than the mask of the existing FMM technology because of the larger width of the opening and the connecting bridge. The increase in distance between different pixels is beneficial to avoid color mixing, which is beneficial to improve product yield, larger evaporation alignment margin, lower FMM replacement frequency leading to increased productivity, and reduced FMM cleaning loss. In the case that the width of the mask opening is the same as that of the existing FMM technology, the FMM connection bridge is wider and is not easily deformed, which can produce an OLED display with a higher pixel density. OLED device pixel arrangement design and evaporation method can both improve device resolution, improve the operability of FMM production and evaporation process, improve productivity and yield, and can provide OLED devices with excellent reliability and display quality at a low cost and stability.

The above embodiments are only used to describe the technical solution of the present application, but not limited thereto. Although the present application has been described in detail with reference to the foregoing embodiments, those of ordinary skill in the art should understand that they can still modify the technical solutions described in the foregoing embodiments, or equivalently replace some of the technical features; and these modifications or replacements do not depart from the spirit and scope of the technical solutions of the embodiments of the present application.

### INDUSTRIAL APPLICABILITY

The subject matter of the present application can be manufactured and used in industry and has industrial applicability.

1. A pixel arrangement evaporation method capable of improving color gamut and pixels per inch (PPI), comprising following steps of:
a step S1 of using adjacent-closely pixels with same appearance and color on an evaporation substrate as independent units;
a step S2 of setting number of sub-pixels of each of the independent units to 3N+1 or 3N+2, where N is a positive integer;
a step S3 of setting fine metal mask (FMM) openings on the evaporation substrate; and
a step S4 of evaporating all of pixel arrangement methods set in the step S2 and a same unit to form a film by using an evaporation method of a same FMM opening.

2. The pixel arrangement evaporation method capable of improving color gamut and PPI according to claim 1, wherein in the step S4, an evaporation zone is included during evaporation, and the evaporation zone is provided with an evaporation unit, an evaporation source, and an evaporation mask.

3. The pixel arrangement evaporation method capable of improving color gamut and PPI according to claim 2, wherein the evaporation source is provided with evaporation source openings, each of evaporation source openings emits evaporation particles, and a restriction unit is used to set restriction openings through which the evaporation particles emitted from the evaporation source openings respectively pass.

4. The pixel arrangement evaporation method capable of improving color gamut and PPI according to claim 2, wherein the evaporation mask is provided with evaporation openings in the vapor deposition areas where the vapor deposition particles reach the restriction openings respectively.

5. The pixel arrangement evaporation method capable of improving color gamut and PPI according to claim 2, wherein an evaporation beam direction adjustment plate having evaporation beam passage holes is disposed and formed between the evaporation source and the evaporation mask, wherein a direction of an evaporation beam is controlled by passing the evaporation particles discharged from the evaporation source through an evaporation beam passage hole formed in the evaporation beam direction adjustment plate.

6. The pixel arrangement evaporation method capable of improving color gamut and PPI according to claim 3, wherein the evaporation source openings are arranged at a fixed pitch along an X-axis direction, and each of the evaporation source openings has a nozzle shape opening upward parallel to a Z axis and emits the evaporation particles as material of a light-emitting layer toward the evaporation mask.

7. The pixel arrangement evaporation method capable of improving color gamut and PPI according to claim 4, wherein the evaporation mask is a plate having a main surface parallel to an XY plane, wherein a plurality of mask openings are formed at different positions, in the X-axis direction, along the X-axis direction, wherein an opening shape of the mask openings is a triangular shape parallel to the Y axis.

8. The pixel arrangement evaporation method capable of improving color gamut and PPI according to claim 1, wherein shape of the FMM opening is a triangle or a polygon other than the triangle.

9. A pixel arrangement display device capable of improving color gamut and PPI, the pixel arrangement display device used to implement the pixel arrangement evaporation method capable of improving color gamut and PPI according to claim 1, the pixel arrangement display device comprising: a display device and an evaporation substrate, wherein the display device comprises a plurality of pixels, and each of the plurality of pixels includes a plurality of sub-pixels of different colors, wherein on the evaporation substrate, an R pixel, a G pixel, and a B pixel that are triangular in shape, independently controllable, and light-emitting are sequentially arranged on the evaporation substrate, wherein adjacent-closely pixels with same appearance and color on an evaporation substrate are used as independent units, wherein number of the pixels in three single-color independent units can be the same in the independent units arranged in a same row.

10. The pixel arrangement display device capable of improving color gamut and PPI according to claim 9, wherein the R pixel is a red color triangle, the G pixel is a green color triangle, and the B pixel is a blue color triangle, wherein the sub-pixels with the same pixel color in the independent unit are adjacent to each other symmetrically, and widths of the longitudinal edges are equal to widths of the adjacent edges of an area composed of adjacent sub-pixels with the same color.

11. The pixel arrangement display device capable of improving color gamut and PPI according to claim 9, wherein an evaporation zone is included during evaporation, and the evaporation zone is provided with an evaporation unit, an evaporation source, and an evaporation mask.

12. The pixel arrangement display device capable of improving color gamut and PPI according to claim 11, wherein the evaporation source is provided with evaporation source openings, each of evaporation source openings emits evaporation particles, and a restriction unit is used to set restriction openings through which the evaporation particles emitted from the evaporation source openings respectively pass.

13. The pixel arrangement display device capable of improving color gamut and PPI according to claim 11, wherein the evaporation mask is provided with evaporation openings in the vapor deposition areas where the vapor deposition particles reach the restriction openings respectively.

14. The pixel arrangement display device capable of improving color gamut and PPI according to claim 11, wherein an evaporation beam direction adjustment plate having evaporation beam passage holes is disposed and formed between the evaporation source and the evaporation mask, wherein a direction of an evaporation beam is controlled by passing the evaporation particles discharged from the evaporation source through a evaporation beam passage hole formed in the evaporation beam direction adjustment plate.

15. The pixel arrangement display device capable of improving color gamut and PPI according to claim 12, wherein the evaporation source openings are arranged at a fixed pitch along an X-axis direction, and each of the evaporation source openings has a nozzle shape opening upward parallel to a Z axis and emits the evaporation particles as material of a light-emitting layer toward the evaporation mask.

16. The pixel arrangement display device capable of improving color gamut and PPI according to claim 13, wherein the evaporation mask is a plate having a main surface parallel to an XY plane, wherein a plurality of mask openings are formed at different positions, in the X-axis direction, along the X-axis direction, wherein an opening shape of the mask openings is a triangular shape parallel to the Y axis.

17. The pixel arrangement display device capable of improving color gamut and PPI according to claim 9, wherein shape of the FMM opening is a triangle or a polygon other than the triangle.
